(19) United States
(12) Patent Application Publication
(10) Pub. No.: US 2020/0368856 A1
(43) Pub. Date: Nov. 26, 2020

(54) DIAMOND BLADE AND METHOD OF MANUFACTURING THE SAME

(71) Applicant: National Taiwan University of Science and Technology, Taipei (TW)

(72) Inventors: Jinn P. Chu, Taipei (TW); Bo-Zhang Lai, Taipei (TW)

(73) Assignee: National Taiwan University of Science and Technology, Taipei (TW)

(21) Appl. No.: 16/719,936

(22) Filed: Dec. 18, 2019

Related U.S. Application Data
(60) Provisional application No. 62/851,827, filed on May 23, 2019.

(51) Int. Cl. B23P 5/00; B23P 15/28; C22C 16/00; C23C 14/35

(52) U.S. Cl. CPC B23P 5/00; B23P 15/28; H01J 37/3405; C23C 14/35; C22C 16/00

(57) ABSTRACT

A diamond blade includes a base and a thin film metallic glass. The base includes a plurality of diamond particles, and the plurality of diamond particles protrude from a surface of the base. The thin film metallic glass is formed on the surface of the base, and the plurality of diamond particles are exposed on the thin film metallic glass.

### CROSS-REFERENCE TO RELATED APPLICATION

This application claims the priority benefits of U.S. provisional application Ser. No. 62/851,827, filed on May 23, 2019, the entirety of which is hereby incorporated by reference herein and made a part of this specification.

### BACKGROUND OF THE INVENTION

### 1. Field of the Invention

The present disclosure generally relates to a diamond blade, and more particularly to a diamond blade comprising a metallic glass material. The present disclosure further comprises a method of manufacturing the diamond blade.

### 2. Description of the Related Art

In the semiconductor industry, diamond blades are often used to perform wafer dicing operations to manufacture integrated circuits, electromechanical components and the like. Since the wafer is mostly made of a hard and brittle material, defects such as sidewall chipping or damage easily occur on two sides of the kerf during the wafer dicing process. Although the common diamond blade has sufficient hardness to facilitate wafer dicing, the debris generated by the diamond blade during the wafer dicing process cannot be smoothly removed outside the kerf and increases the number and size of the sidewall chippings on two sides of the kerf. Accordingly, it is necessary to reserve spaces on two sides of each kerf for sidewall chippings before the wafer is diced, and such a practice will cause yield losses in the semiconductor manufacturing process.

Therefore, there is a need to provide a diamond blade with a better debris removal effect and better durability.

### SUMMARY OF THE INVENTION

A primary object of this disclosure is to provide a diamond blade comprising a metallic glass material.

To achieve the aforesaid and other objects, the diamond blade of this disclosure comprises a base and a thin film metallic glass. The base comprises a plurality of diamond particles, and the plurality of diamond particles protrude from a surface of the base. The thin film metallic glass is formed on the surface of the base, and the plurality of diamond particles are exposed on the thin film metallic glass.

In one embodiment of this disclosure, the thin film metallic glass is a continuous thin film without any columnar structure.

In one embodiment of this disclosure, the thin film metallic glass is deposited on the surface of the base by a high-power impulse magnetron sputtering proces.

In one embodiment of this disclosure, the thin film metallic glass comprises a zirconium-based metallic glass material.

In one embodiment of this disclosure, the zirconium-based metallic glass material comprises a ZrₐCu_{b}Al_{c}Ni_{d} alloy, wherein a is 61.7±0.2 at %, b is 24.6±0.1 at %, c is 7.7±0.1 at % and d is 6.0±0.1 at %, and wherein a+b+c+d=100.

In one embodiment of this disclosure, the base comprises an edge with a chamfer angle, and the chamfer angle is 60±2 degrees.

In one embodiment of this disclosure, the plurality of diamond particles are fixed on the surface of the base by bonding.

Another object of this disclosure is to provide the method of manufacturing the diamond blade. The method comprises: providing a base comprising a plurality of diamond particles, and the plurality of diamond particles protrude from a surface of the base; performing a first dressing of the base; depositing a thin film metallic glass on the surface of the base; and performing a second dressing of the base to remove a redundant part of the thin film metallic glass coated on the plurality of diamond particles, such that the plurality of diamond particles are exposed on the thin film metallic glass.

In one embodiment of this disclosure, the thin film metallic glass is deposited on the surface of the base by a high-power impulse magnetron sputtering process with a metallic glass alloy target.

In one embodiment of this disclosure, the high-power impulse magnetron sputtering process is performed under the conditions of a sputtering power of 2-3 kW, a pulsed voltage of 500-700 V and a pulsed current of 150-170 A.

### BRIEF DESCRIPTION OF THE DRAWINGS

The accompanying drawings are included to provide further understanding of the invention and are incorporated in and constitute a part of this specification. The drawings illustrate embodiments of the invention and, together with the descriptions, serve to explain the principles of the invention.

FIG. 1 illustrates a schematic view of a diamond blade of this disclosure.

FIG. 2 illustrates a cross-sectional view of the diamond blade of this disclosure along line B-B′.

FIG. 3 illustrates a flowchart of a method of manufacturing the diamond blade of this disclosure.

FIG. 4 illustrates cross-sectional images of the experimental example C and the comparative example D of the diamond blade of this disclosure after the deposition of a thin film metallic glass by different techniques.

FIG. 5 illustrates the hardnesses of the experimental example C and the comparative example D of the diamond blade of this disclosure.

FIG. 6 illustrates a top view of an example of a kerf after wafer dicing.

FIG. 7 illustrates top views of kerfs after twenty cuts were performed on a silicon wafer by the experimental example E and the comparative example F of the diamond blade of this disclosure.

FIG. 8 illustrates the relationship between the kerf distances, the kerf depths, and the angles of the kerfs after twenty cuts were performed on the silicon wafer by the experimental example E and the comparative example F of the diamond blade of this disclosure.

### DESCRIPTION OF THE EMBODIMENTS

Since the various aspects and embodiments described herein are merely exemplary and not limiting, after reading this specification, skilled artisans will appreciate that other aspects and embodiments are possible without departing from the scope of the disclosure. Other features and benefits of any one or more of the embodiments will be apparent from the following detailed description and the claims.

The use of “a” or “an” is employed to describe elements and components described herein. This is done merely for convenience and to give a general sense of the scope of the invention. Accordingly, this description should be read to include one or at least one and the singular also includes the plural unless it is obvious that it is meant otherwise.

As used herein, the terms “comprises,” “comprising,” “includes,” “including,” “has,” “having” or any other variation thereof are intended to cover a non-exclusive inclusion. For example, a component, structure, article, or apparatus that comprises a list of elements is not necessarily limited to only those elements but may include other elements not expressly listed or inherent to such component, structure, article, or apparatus.

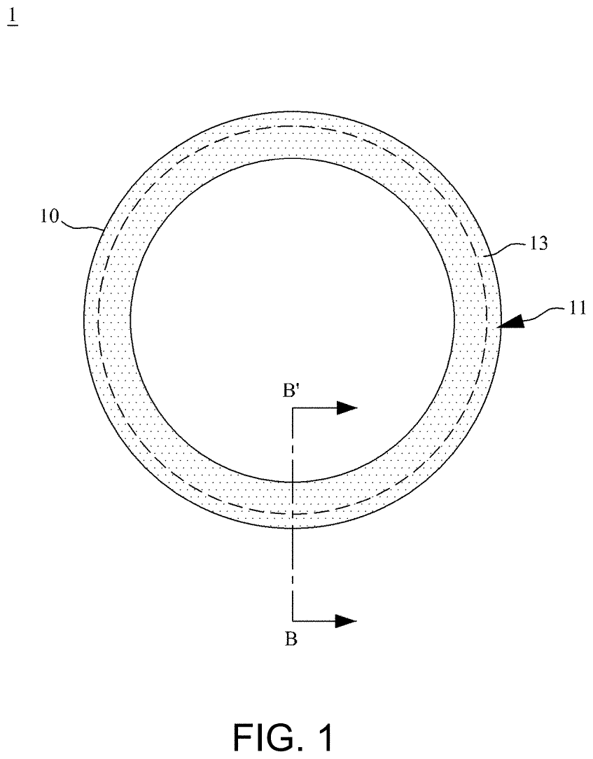

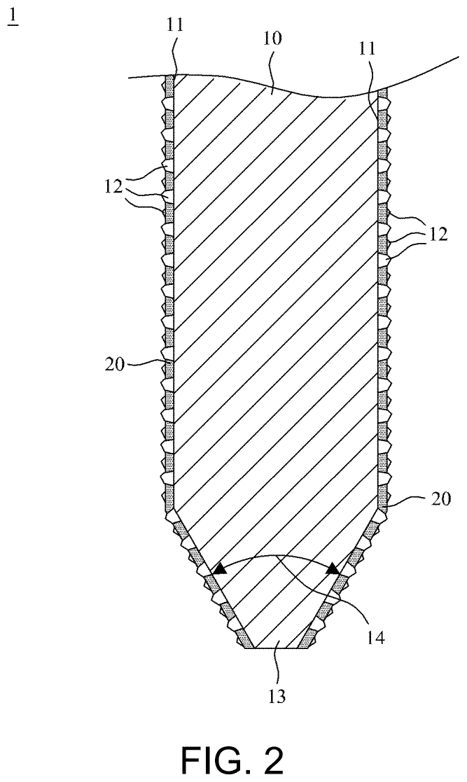

Please refer to FIG. 1 and FIG. 2. FIG. 1 illustrates a schematic view of a diamond blade of this disclosure, and FIG. 2 illustrates a cross-sectional view of the diamond blade of this disclosure along line BB′. As illustrated in FIG. 1 and FIG. 2, the diamond blade 1 of this disclosure comprises a base 10 and a thin film metallic glass 20. The base 10 is used as a main structural member of the diamond blade 1 of this disclosure, and the base 10 comprises a surface 11 and an edge 13. The base 10 is made by sintering a metal material, such as Fe—Co—Sn alloy, but this disclosure is not limited thereto. In one embodiment of this disclosure, the base 10 is a ring blade, but the shape of the base 10 can also be changed according to different use requirements. The surface 11 of the base 10 comprises two symmetrical planes of the ring blade, and the edge 13 of the base 10 is mainly disposed at the outer ring of the ring blade.

The base 10 further comprises a plurality of diamond particles 12, and the plurality of diamond particles 12 are irregularly fixed on the surface 11 of the base 10.

The plurality of diamond particles 12 can be fixed on a partial surface of the edge 13 or the entire surface 11 of the base 10. In one embodiment of this disclosure, the plurality of diamond particles 12 are fixed on the surface 11 of the base 10 by bonding. For example, the plurality of diamond particles 12 are fixed on the surface 11 of the base 10 in conjunction with a binder by a resin bonding method, a metal-sintered bonding method, an electroplated nickel bonding method or a combination of any two or more of the foregoing bonding methods, but this disclosure is not limited thereto. The plurality of diamond particles 12 protrude from the surface 11 of the base 10 to facilitate the dicing process. It should be noted that in order to show the combination of the plurality of diamond particles 12 and the base 10, the plurality of diamond particles 12 are presented in a relatively regular arrangement in FIG. 2, but in fact the plurality of diamond particles 12 are arranged irregularly on the surface 11 of the base 10.

Furthermore, in order to conform to the requirements for dicing wafers (e.g., silicon wafers, sapphire wafers, patterned sapphire substrates, etc.), in one embodiment of this disclosure, a chamfer angle A is formed at the edge 13 of the base 10. Due to the chamfer angle A of the edge 13, the two sides of the kerf formed on the wafer by the diamond blade 1 of this disclosure may be corresponded to the shape of the chamfer angle A during the wafer dicing process. In one embodiment of this disclosure, the chamfer angle A of the edge 13 is about 60±2 degrees, but this disclosure is not limited thereto.

The thin film metallic glass 20 is formed on the surface 11 of the base 10. The thin film metallic glass 20 is mainly used as a structural reinforcement of the diamond blade 1 of this disclosure for enhancing the debris removal effect and the structural strength of the diamond blade 1 of this disclosure. The thin film metallic glass 20 can cover only a part of the surface 11 comprising the edge 13 or the entire surface 11 of the base 10. In particular, the plurality of diamond particles 12 are exposed on the thin film metallic glass 20. In other words, at least a portion of each of the diamond particles 12 protrudes from the surface of the thin film metallic glass 20 without being covered by the thin film metallic glass 20. The plurality of diamond particles 12 are exposed for wafer dicing during the wafer dicing process.

In one embodiment of this disclosure, the thin film metallic glass 20 is deposited on the surface 11 of the base 10 by a high-power impulse magnetron sputtering process with a metallic glass target. The thin film metallic glass 20 formed by the high-power impulse magnetron sputtering process is a continuous thin film without any columnar structure to improve the debris removal effect and structural strength.

In one embodiment of this disclosure, the thin film metallic glass 20 comprises a zirconium-based metallic glass material, but this disclosure is not limited thereto. The thin film metallic glass 20 may also comprise other metallic glass materials having similar characteristics. Taking a zirconium-based metallic glass material as an example, in one embodiment of this disclosure, the zirconium-based metallic glass material comprises a ZrₐCu_{b}Al_{c}Ni_{d} alloy, wherein a is 61.7±0.2 at %, b is 24.6±0.1 at %, c is 7.7±0.1 at % and d is 6.0±0.1 at %, and wherein a+b+c+d=100.

Here, the thin film metallic glass 20 has an amorphous structure, in which the atoms are arranged irregularly or without specific order in the structure. The thin film metallic glass 20 has several satisfactory properties including no grain boundary defects, high mechanical strength and toughness, high resistance to corrosion and wear, a low friction coefficient and the ability to provide a smooth hydrophobic surface at room temperature. Accordingly, the diamond blade 1 of this disclosure can provide better debris removal characteristics due to the thin film metallic glass 20 deposited on the base 10.

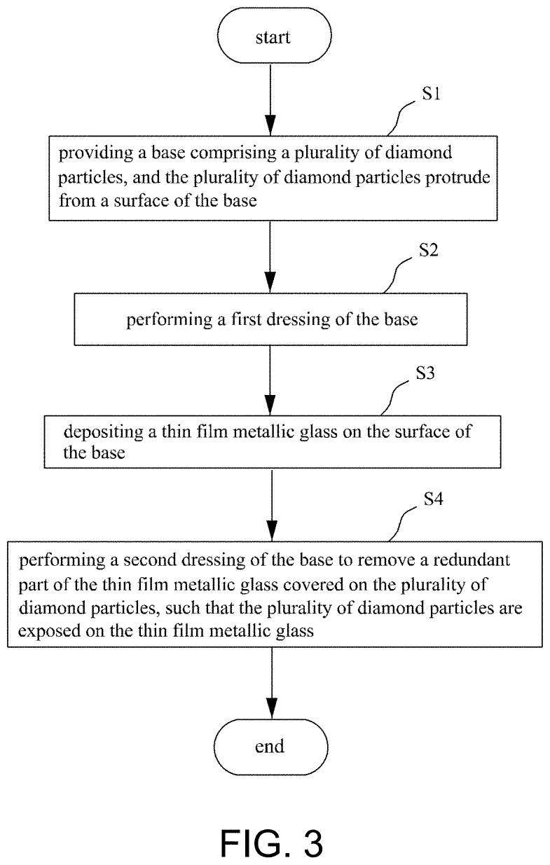

Now refer to FIG. 3. FIG. 3 illustrates a flowchart of a method of manufacturing the diamond blade of this disclosure. As illustrated in FIG. 3, the method of manufacturing the diamond blade of this disclosure comprises step S1 to step S4, which are described in detail below.

Step S1: Providing a base comprising a plurality of diamond particles, and the plurality of diamond particles protrude from a surface of the base.

First, a base 10 suitable for application as a main structural member of the diamond blade 1 of this disclosure is provided. In the following description, the base 10 is exemplified by a Fe—Co—Sn alloy sintered diamond blade (model SDC600N75 MHZ) produced by Taiwan Diamond Co., Ltd., but this disclosure is not limited thereto. Since the base 10 is substantially a thin blade, the surface 11 of the base 10 comprises two symmetrical planes formed on two sides of the base 10. The base 10 comprises the plurality of diamond particles 12, and the plurality of diamond particles 12 are fixed on and protrude from the surface 11 of the base 10.

Step S2: Performing a first dressing of the base.

After the base 10 has been provided in Step S1, a first dressing is performed on the base 10. After the plurality of diamond particles 12 are bonded to the base 10, the outer surfaces of the plurality of diamond particles 12 may be covered by residual binder or other impurities, thereby affecting the dicing effect of the plurality of diamond particles 12. It is necessary to perform the first dressing of the base 10 to remove the aforementioned residual binder or other impurities. Accordingly, the plurality of diamond particles 12 can be exposed on the surface 11 of the base 10 after the first dressing is performed on the base 10.

A whetstone can be utilized for perform the first dressing of the base 10. In one embodiment of this disclosure, ten cuts can be performed on the whetstone produced by Asahi Diamond Industrial Australia Pty. Ltd. (model WA600L) for dressing the base 10 under the conditions of a rotational spindle speed of about 35,000 rpm, a feed rate of about 5 mm/sec, a cutting depth of about 0.4 mm, and cooling with de-ionized water of about 20° C., but this disclosure is not limited thereto.

Step S3: Depositing a thin film metallic glass on the surface of the base.

After the first dressing has been performed on the base 10 in Step S2, a thin film metallic glass 20 is deposited on the surface 11 of the base 10 by a high-power impulse magnetron sputtering process. In one embodiment of this disclosure, a single metallic glass alloy target is sputtered onto the base 10 by the high-power impulse magnetron sputtering process to deposit the thin film metallic glass 20 on the surface 11 of the base 10. In this embodiment, the metallic glass alloy target may be a zirconium-based metallic glass material comprising a ZrₐCu_{b}Al_{c}Ni_{d} alloy. The operating conditions for the high-power impulse magnetron sputtering process are a sputtering power of about 2-3 kW, a pulsed voltage of about 500-700 V and a pulsed current of about 150-170 A, but this disclosure is not limited thereto. The thickness of the thin film metallic glass 20 deposited on the surface 11 of the base 10 is about 100 nm to 1 μm after sputtering.

Furthermore, during the deposition of the thin film metallic glass 20 on the surface 11 of the base 10 in Step S3, the surface 11 of one side of the base 10 is oriented such that it faces toward the metallic glass alloy target for the deposition of the thin film metallic glass 20. After the thin film metallic glass 20 is deposited to a desired thickness, the surface 11 of the opposite side of the base 10 is oriented such that it faces toward the metallic glass alloy target by rotating the base 10 to continuously deposit the thin film metallic glass 20. Accordingly, the thin film metallic glass 20 can uniformly cover the surface 11 of the base 10.

Step S4: Performing a second dressing of the base to remove a redundant part of the thin film metallic glass coated on the plurality of diamond particles, such that the plurality of diamond particles are exposed on the thin film metallic glass.

After the thin film metallic glass 20 has been deposited on the surface 11 of the base 10 in Step S3, a second dressing is performed on the base 10. Since the plurality of diamond particles 12 protruding from the surface 11 of the base 10 are also covered by the thin film metallic glass 20 after the thin film metallic glass 20 has been deposited on the base 10, the dicing effect of the plurality of diamond particles 12 will be affected. Therefore, it is necessary to perform the second dressing of the base 10 to remove a redundant part of the thin film metallic glass 20 coated on the plurality of diamond particles 12. Accordingly, the plurality of diamond particles 12 will be exposed on the deposited thin film metallic glass 20 after the second dressing is performed on the base 10.

An automatic dicing saw system can be utilized to perform the second dressing of the base 10. In one embodiment of this disclosure, a down cut mode can be performed by the automatic dicing saw system produced by DISCO Corporation, Japan (model DAD322) for dressing the base 10 under the conditions of a rotational spindle speed of about 25,000 rpm, a feed rate of about 5 mm/sec, and cooling with de-ionized water of about 20° C., but this disclosure is not limited thereto.

Therefore, after the second dressing, the diamond blade 1 of this disclosure can be applied to operations such as wafer dicing.

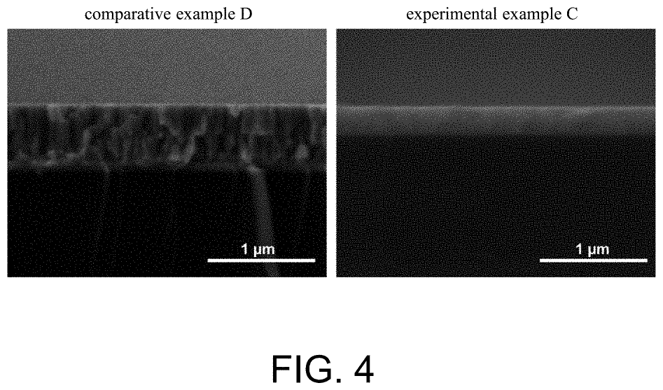

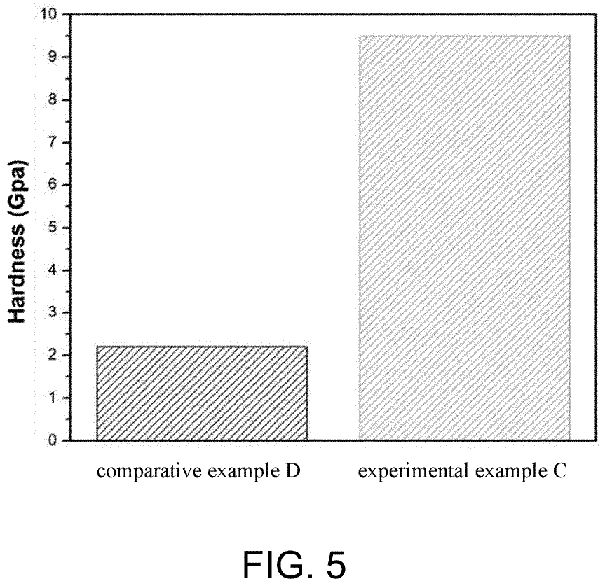

Refer to FIG. 4 and FIG. 5. FIG. 4 illustrates cross-sectional images of the experimental example C and the comparative example D of the diamond blade of this disclosure after the deposition a thin film metallic glass by different techniques; FIG. 5 illustrates the hardnesses of the experimental example C and the comparative example D of the diamond blade of this disclosure. In the following experiments, under the same working pressure (3.8 mTorr) and materials, a base 10 on which a thin film metallic glass 20 was deposited by a high-power impulsed magnetron sputtering process with a sputtering power of 2.5 kW was used as an experimental example C of the diamond blade, and a base 10 on which a thin film metallic glass 20 was deposited by a DC magnetron sputtering process with a sputtering power of 300 W was used as a comparative example D of the diamond blade. Cross-sectional images of the thin film metallic glass 20 of the experimental example C and the comparative example D were photographed with an electron microscope. Metallic glass alloy targets comprising a

Zr_{61.7}Cu_{24.6}Al_{7.7}Ni₆ alloy were used in the above different sputtering processes, and the bases 10 were made by sintering the same Fe—Co—Sn alloy.

As illustrated in FIG. 4, the comparative example D, in which the thin film metallic glass 20 was deposited by the DC magnetron sputtering process, and the experimental example C, in which the thin film metallic glass 20 was deposited by the high-power impulse magnetron sputtering process, were significantly different in structure. The deposited thin film metallic glass 20 in the comparative example D had many fine columnar structures, indicating that during the deposition, the thin film metallic glass 20 underwent re-nucleation, which resulted in a non-continuous structure of the thin film. Therefore, the structural strength and characteristics of the thin film metallic glass 20 was affected. In contrast, the deposited thin film metallic glass 20 in the experimental example C did not have a columnar structure and was continuous.

As illustrated in FIG. 5, the hardness values of the thin film metallic glass 20 of the experimental example C and the comparative example D were measured by indentation with 1000 μN. According to the statistical experimental data, the hardness value of the thin film metallic glass 20 of the comparative example D was about 2.2 Gpa, and the hardness value of the thin film metallic glass 20 of the experimental example C was about 9.5 Gpa. Accordingly, the thin film metallic glass 20 of the experimental example C had a continuous and dense structure and thus a higher hardness and higher resistance to deformation and wear.

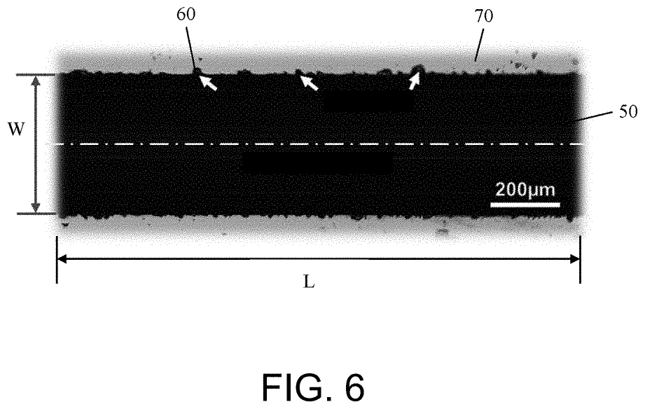

Furtherfore, the chipping area fraction calculated from the kerf after wafer dicing is an important factor for judging the performance of different diamond blades. Please refer to FIG. 6, which illustrates a top view of an example of a kerf after wafer dicing. As illustrated in FIG. 6, taking a silicon wafer as an example, a long kerf 50 was formed after the silicon wafer was cut by the diamond blade. The length and width of the kerf 50 will vary according to the different types of diamond blades and different cutting distances. Chippings 60 (as indicated by the arrow in the figure) may be formed on two sidewalls 70 of the kerf 50. The larger the calculated chipping area fraction is, the larger the number and size of the chippings 60 that form on two sides of the kerf 50 are. The calculation formula of the aforementioned chipping area fraction is as follows:

Area(%)=((A_{R}−W×L)/(W×L))×100%

where Area is the fraction of the chipping area per kerf area, AR is the dark area (indicated by the black region in the figure, including the kerf 50 and chippings 60), W is the kerf width, and L is the distance of the kerf midline.

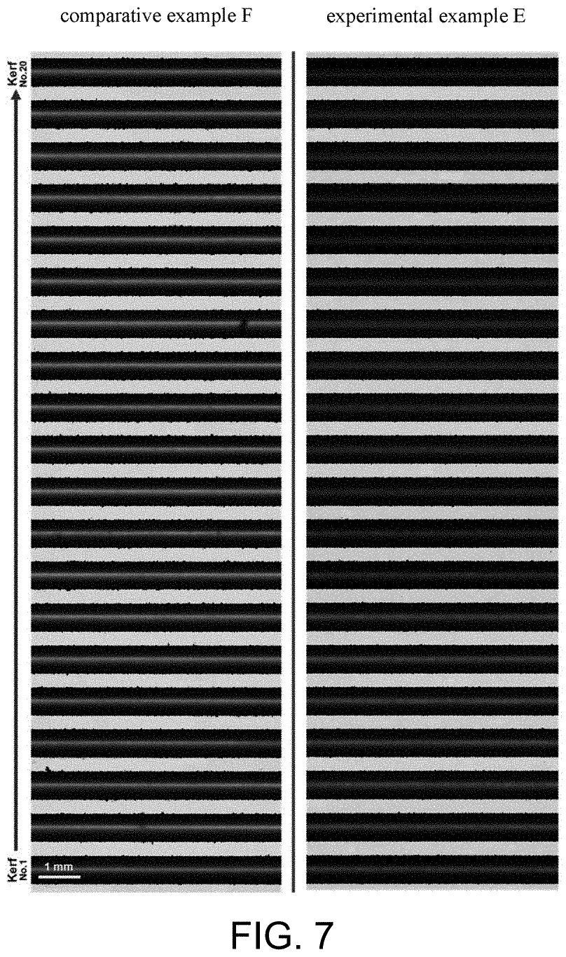

Please refer to FIG. 7 and Table 1. FIG. 7 illustrates top views of kerfs after twenty cuts were performed on a silicon wafer by the experimental example E and the comparative example F of the diamond blade of this disclosure. In the following experiments, a diamond blade with a thin film metallic glass deposited on a base was used as an experimental example E, and a diamond blade without a thin film metallic glass deposited on a base was used as a comparative example F. The bases were made by sintering the same Fe—Co—Sn alloy, and the thin film metallic glass comprised a Zr_{6.17}Cu_{24.6}Al_{7.7}Ni₆ alloy. Twenty cuts were continuously performed on a silicon wafer with a thickness of about 525 μm by the experimental example E and the comparative example F of the diamond blade, and top views of the cut silicon wafer were photographed with an electron microscope. The average distance of the kerf 50 was about 3880.4 mm, and the average depth of the kerf 50 was about 400 μm per cutting. The distance between the two adjacent kerfs 50 was about 200 μm. The results of the chipping area fraction calculated according to each kerf are shown in Table 1.

TABLE 1

Chipping area fraction

| | Comparative | Experimental |
|---|---|---|
| Kerf No. | example F | example E |
| 1 | 2.53% | 1.42% |
| 2 | 2.46% | 1.83% |
| 3 | 2.37% | 0.97% |
| 4 | 2.50% | 2.26% |
| 5 | 2.74% | 2.11% |
| 6 | 2.37% | 2.03% |
| 7 | 1.88% | 2.12% |
| 8 | 2.71% | 2.08% |
| 9 | 2.51% | 1.15% |
| 10 | 3.09% | 1.59% |
| 11 | 2.26% | 2.06% |
| 12 | 2.09% | 1.52% |
| 13 | 1.92% | 1.80% |
| 14 | 1.86% | 1.64% |
| 15 | 1.56% | 1.73% |
| 16 | 1.85% | 1.83% |
| 17 | 2.03% | 2.23% |
| 18 | 2.44% | 1.80% |
| 19 | 1.92% | 1.40% |
| 20 | 2.77% | 1.75% |
| Average | 2.29 ± 0.38% | 1.77 ± 0.34% |

As shown in FIG. 7 and Table 1, the average chipping area fraction of the comparative example F was about 2.29±0.38%, and the average chipping area fraction of the experimental example E was about 1.77±0.34%. Therefore, the average chipping area fraction of the experimental example E was approximately 23% smaller than the average chipping area fraction of the comparative example F. Accordingly, the chipping area fraction of the diamond blade of the disclosure can be effectively reduced due to the deposition of the thin film metallic glass. In other words, the number and size of chippings formed on the sidewalls of the kerf can be effectively reduced by using the diamond blade of this disclosure during the silicon wafer dicing process. The diamond blade of this disclosure can provide a better dicing effect and quality.

Moreover, the wear resistance of the diamond blade can be judged mainly based on the depth and angle changes of the kerfs formed by the diamond blade after wafer dicing is performed multiple times. The kerf depth is influenced by automatic alignment of the diameter of the diamond blade, the thickness of the wafer, the thickness of the dicing tape, and the air bubbles between the wafer and the dicing tape. Therefore, the kerf depth is rarely fully matched to the set dicing depth in the common wafer dicing process. In addition, the angle of the kerf should be as close as possible to the chamfer angle of the diamond blade to reduce the formation of debris from cutting.

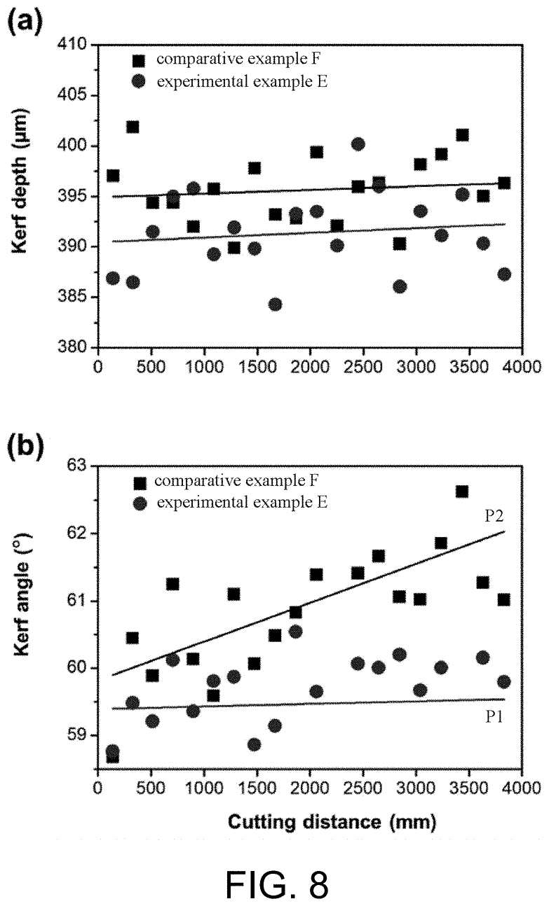

Please refer to FIG. 8 and Table 2. FIG. 8 illustrates the relationship between the kerf distances, the kerf depths, and the angles of the kerfs after twenty cuts were performed on the silicon wafer by the experimental example E and the comparative example F of the diamond blade of this disclosure. In the following experiments, the aforementioned diamond blades were used as the experimental example E and the comparative example F. Twenty cuts were continuously performed on a silicon wafer with a thickness of about 525 μm by the experimental example E and the comparative example F of the diamond blade, and the depths and the angles of the kerfs formed by cutting were measured. The results are shown in Table 2. The cutting distance of each cut was different, and the cut depth was set to 400 μm. The chamfer angle of the diamond blade was 60 degrees.

TABLE 2

| | Cutting | | | | |
|---|---|---|---|---|---|
| | distance | | | | |
| | at kerf | Comparative example F | | Experimental example E | |
| Kerf | midpoint | Angle | Kerf depth | Angle | Kerf depth |
| No. | (mm) | (degrees) | (μm) | (degrees) | (μm) |
| 1 | 139.2 | 58.7 | 397.0 | 58.8 | 386.9 |
| 2 | 326.2 | 60.5 | 401.9 | 59.5 | 386.5 |
| 3 | 514.8 | 59.9 | 394.3 | 59.2 | 391.5 |
| 4 | 705.0 | 61.3 | 394.4 | 60.1 | 395.0 |
| 5 | 896.6 | 60.1 | 392.0 | 59.4 | 395.8 |
| 6 | 1088.9 | 59.6 | 395.8 | 59.8 | 389.3 |
| 7 | 1281.8 | 61.1 | 389.9 | 59.9 | 391.9 |
| 8 | 1475.4 | 60.1 | 397.8 | 58.9 | 389.8 |
| 9 | 1669.5 | 60.5 | 393.2 | 59.1 | 384.3 |
| 10 | 1864.2 | 60.8 | 392.8 | 60.5 | 393.3 |
| 11 | 2059.3 | 61.4 | 399.4 | 59.6 | 393.5 |
| 12 | 2254.8 | 63.3 | 392.1 | 57.2 | 390.1 |
| 13 | 2450.7 | 61.4 | 396.0 | 60.1 | 400.2 |
| 14 | 2647.0 | 61.7 | 396.3 | 60.0 | 396.0 |
| 15 | 2843.6 | 61.1 | 390.3 | 60.2 | 386.0 |
| 16 | 3040.4 | 61.0 | 398.2 | 59.7 | 393.5 |
| 17 | 3237.4 | 61.9 | 399.2 | 60.0 | 391.1 |
| 18 | 3434.7 | 62.6 | 401.1 | 57.4 | 395.2 |
| 19 | 3632.1 | 61.3 | 395.0 | 60.2 | 390.3 |
| 20 | 3829.6 | 61.0 | 396.3 | 59.8 | 387.3 |

| | | | | |
|---|---|---|---|---|
| Average | 61.0 ± 1.0 | 395.6 ± 3.3 | 59.5 ± 0.8 | 391.4 ± 3.9 |

As shown in FIG. 8 and Table 2, the average kerf depth of the comparative example F was about 395.6±3.3 μm, and the average kerf depth of the experimental example E was about 391.4±3.9 μm. Both of them were lower than the set cut depth of 400 μm. In addition, with both the experimental example E and the comparative example F, the kerf depth tended to increase steadily as the cut distance of the formed kerf increased.

Furthermore, the average kerf angle of the comparative example F was about 61.0±1.0 degrees, and the average kerf angle of the experimental example E was about 59.5±0.8 degrees. Therefore, the average kerf angle formed by the experimental example E was significantly lower than that of the comparative example F and was closer to the chamfer angle of the diamond blade by 60 degrees. In addition, according to FIG. 8 and linear analysis performed with statistical experimental data, the gradient of the trend line P1 presented by the linear analysis based on the kerf angles of the experimental example E was significantly smaller than the gradient of the trend line P2 presented by the linear analysis based on the kerf angles of the comparative example F. In other words, the angles of the kerfs can be effectively maintained at close to the chamfer angle of the diamond blade even after multiple cuttings are performed by the diamond blade of this disclosure in the wafer dicing process. Therefore, the likelihood of the formation of debris may be reduced.

In addition, during the wafer dicing process, de-ionized water may be provided for flushing the kerf and removing debris from the kerf. Since the deposited thin film metallic glass of the diamond blade of this disclosure has a low friction coefficient and a good hydrophobic property, the smooth hydrophobic surface of the thin film metallic glass facilitates the removal the debris from the kerf with deionized water during the wafer dicing process. Accordingly, the possibility of the formation of chippings on the sidewalls of the kerf due to debris accumulation may be reduced.

It should be noted that the silicon wafers are employed as examples to illustrate the wafer dicing process performed with each experimental example and each comparative example of the diamond blade of this disclosure in the foregoing experiments, but sapphire wafers, pattern sapphire substrates or other wafers of different materials may also be used as targets for cutting, and this disclosure is not limited thereto.

In summary, the diamond blade of this disclosure improves the strength, wear resistance and hydrophobic properties of the base due to the deposition of a thin film metallic glass on the surface of the base. Accordingly, the diamond blade of this disclosure can reduce the formation of debris and sidewall chippings on two sides of the kerf during the wafer dicing process and contributes to the improvement of the debris removal effect.

The above detailed description is merely illustrative in nature and is not intended to limit the embodiments of the subject matter or the application and uses of such embodiments. Moreover, while at least one exemplary embodiment has been presented in the foregoing detailed description, it should be appreciated that a vast number of variations exist. It should also be appreciated that the exemplary one or more embodiments described herein are not intended to limit the scope, applicability, or configuration of the claimed subject matter in any way. Rather, the foregoing detailed description will provide those skilled in the art with a convenient guide for implementing the described one or more embodiments. Also, various changes can be made to the function and arrangement of elements without departing from the scope defined by the claims, which include known equivalents and foreseeable equivalents at the time of filing of this patent application.

What is claimed is:

1. A diamond blade, comprising:
a base comprising a plurality of diamond particles, the plurality of diamond particles protruding from a surface of the base; and
a thin film metallic glass formed on the surface of the base, wherein the plurality of diamond particles are exposed on the thin film metallic glass.

2. The diamond blade of claim 1, wherein the thin film metallic glass is a continuous thin film without a columnar structure.

3. The diamond blade of claim 2, wherein the thin film metallic glass is deposited on the surface of the base by a high-power impulse magnetron sputtering process.

4. The diamond blade of claim 1, wherein the thin film metallic glass comprises a zirconium-based metallic glass material.

5. The diamond blade of claim 4, wherein the zirconium-based metallic glass material comprises a ZrₐCu_{b}Al_{c}Ni_{d} alloy, wherein a is 61.7±0.2 at %, b is 24.6±0.1 at %, c is 7.7±0.1 at % and d is 6.0±0.1 at %, and wherein a+b+c+d=100.

6. The diamond blade of claim 1, wherein the base comprises an edge with a chamfer angle, and the chamfer angle is 60±2 degrees.

7. The diamond blade of claim 1, wherein the plurality of diamond particles are fixed on the surface of the base by bonding.

8. A method of manufacturing the diamond blade as recited in claim 1, comprising:
providing a base comprising a plurality of diamond particles, the plurality of diamond particles protruding from a surface of the base;
performing a first dressing of the base;
depositing a thin film metallic glass on the surface of the base; and
performing a second dressing of the base to remove a redundant part of the thin film metallic glass coated on the plurality of diamond particles, such that the plurality of diamond particles are exposed on the thin film metallic glass.

9. The method of claim 8, wherein the thin film metallic glass is deposited on the surface of the base by a high-power impulse magnetron sputtering process with a metallic glass alloy target.

10. The method of claim 9, wherein the high-power impulse magnetron sputtering process is performed under the conditions of a sputtering power of 2-3 kW, a pulsed voltage of 500-700 V and a pulsed current of 150-170 A.
